(19) United States
(12) Patent Application Publication
(10) Pub. No.: US 2024/0047596 A1
(43) Pub. Date: Feb. 8, 2024

(54) HIGH-SPEED QUATERNARY MATERIAL-BASED PHOTODETECTOR

(71) Applicant: Mellanox Technologies, Ltd., Yokneam (IL)

(72) Inventors: Oren Steinberg, Tal Shahar (IL); Anders Gösta Larsson, Hovas (SE); Attila Fülöp, Göteborg (SE); Elad Mentovich, Tel Aviv (IL); Isabelle Cestier, Haifa (IL); Moshe B. Oron, Rehovot (IL)

(73) Assignee: Mellanox Technologies, Ltd., Yokneam (IL)

(21) Appl. No.: 17/883,045

(22) Filed: Aug. 8, 2022

(51) Int. Cl. H01L 31/105; H01L 31/0304

(52) U.S. Cl. CPC H01L 31/105; H01L 31/03046; H01L 31/03042

(57) ABSTRACT

Photodetectors configured to detect light in a particular wavelength range and including a quaternary material are described herein. In some embodiments, the present invention may be directed to a photodetector that includes a collector material that is substantially transparent to the particular wavelength range and a quaternary material adjacent to the collector material, where the quaternary material functions as an absorber material and is lattice-matched to the collector material. A conduction band difference between the collector material and the quaternary material may be approximately zero. Additionally, or alternatively, the photodetector may include a peripheral layer adjacent to the quaternary material, where the peripheral layer is doped with carbon. In some embodiments, the photodetector may include an optical window configured for use with a multi-mode optical fiber.

### FIELD OF THE INVENTION

The present invention relates to high-speed quaternary material-based photodetectors.

### BACKGROUND

With demand for high-speed and high-volume data communication increasing, communications providers are increasingly adopting optics-based communication solutions. To meet these demands, high-speed transmitters and high-speed receivers are being developed.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a photodetector configured to detect light in a particular wavelength range. The photodetector may include an absorber region and a collector region. The absorber region may include a quaternary material and may have an absorber thickness in a direction that is substantially parallel to a detection axis of the photodetector. The quaternary material may have an absorber conduction band energy. The collector region may include a collector material that is substantially transparent to the particular wavelength range and may have a collector thickness in the direction that is substantially parallel to the detection axis. The collector material may have a collector conduction band energy. The absorber conduction band energy and the collector conduction band energy may be approximately equal.

In some embodiments, the photodetector may include an optical window configured for use with a multi-mode optical fiber, where the optical window is positioned in front of the absorber region along the detection axis of the photodetector.

In some embodiments, the absorber region may consist essentially of the quaternary material.

In some embodiments, the quaternary material may be InGaAlAs.

In some embodiments, the collector material may be InP. For example, the collector material may be intrinsic InP.

In some embodiments, the collector region may consist essentially of the collector material.

In some embodiments, the quaternary material may be lattice-matched to the collector material.

In some embodiments, the quaternary material and the collector material may be adjacent to each other along the detection axis.

In some embodiments, the photodetector may include a peripheral layer adjacent the absorber region along the detection axis. For example, the peripheral layer may be p-type doped InAlAs, such as InAlAs doped with carbon or zinc. The peripheral layer may be lattice-matched to the collector material.

In some embodiments, the particular wavelength range may be between 940 nanometers and 1150 nanometers.

In another aspect, the present invention is directed to a photodetector configured to detect light in a particular wavelength range. The photodetector may include a quaternary material, a collector material, and a peripheral layer. The quaternary material may have an absorber thickness in a direction that is substantially parallel to a detection axis of the photodetector. The collector material may be adjacent to a first side of the quaternary material along the detection axis and may be substantially transparent to the particular wavelength range. The collector material may have a collector thickness in the direction that is substantially parallel to the detection axis. The peripheral layer may be adjacent to a second side of the quaternary material along the detection axis.

In some embodiments, the quaternary material may be InGaAlAs.

In some embodiments, the collector material may be intrinsic InP.

In some embodiments, the peripheral layer may be p-type doped InAlAs doped with carbon or zinc.

In yet another aspect, the present invention is directed to a photodetector configured to detect light in a particular wavelength range. The photodetector may include a collector material, a quaternary material, and a peripheral layer. The collector material may be substantially transparent to the particular wavelength range and have a collector thickness in a direction that is substantially parallel to a detection axis of the photodetector. The quaternary material may have an absorber thickness in the direction that is substantially parallel to the detection axis and may be lattice-matched to the collector material. A conduction band difference between the collector material and the quaternary material may be approximately zero. The peripheral layer may be adjacent to the quaternary material along the detection axis and may be doped with carbon.

In some embodiments, the quaternary material may be InGaAlAs, the collector material may be intrinsic InP, and the peripheral layer may be InAlAs doped with carbon or zinc.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made the accompanying drawings, wherein:

FIG. 1 illustrates a cross-section of an example layer structure of a photodetector, in accordance with an embodiment of the invention;

FIG. 2 illustrates a band diagram for the transition between layers within a photodetector, in accordance with an embodiment of the invention;

FIG. 3 illustrates respective band diagrams for a conventional active region and an exemplary active region, in accordance with an embodiment of the invention; and

FIG. 4 illustrates a graph plotting respective frequency responses for a conventional active region and an exemplary active region, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, demand for high-speed and high-volume data communication is increasing, and communications providers are increasingly adopting optics-based communication solutions. To meet these demands, high-speed transmitters and high-speed receivers are being developed. Optical interconnects at 850 nanometers (nm), using GaAs-based multimode vertical-cavity surface-emitting lasers (VCSELs), multi-mode fiber, and multi-mode fiber compatible GaAs-based photodetectors provide superior power and cost efficiency for short-reach applications. VCSEL and photodetector solutions for high data rate (HDR) transceivers and active optical cables capable of 56 Gbit/s, 28 Gbaud PAM4 communication have been developed, and further development of such VCSEL and photodetector technologies is expected to provide transceivers and active optical cables capable of 112 Gbit/s, 56 Gbaud PAM4 network detection and response (NDR) communication. However, technologies for enabling 224 Gbit/s cross-layered detection and response (XDR) communication have yet to be developed.

In particular, the bandwidth of a multi-mode fiber compatible GaAs-based photodetector used for HDR and NDR is limited to about 30 GHz because of the low optical absorption coefficient of GaAs at 850 nm and the relatively low electron and hole drift velocities in GaAs. The thickness of the absorbing GaAs layer required for sufficient responsivity, therefore, limits the response speed in terms of both carrier transit times and capacitance. That is, the thickness of the GaAs layer is too thick for short carrier transport times and is too thin for low capacitance. XDR is expected to require a bandwidth of at least 50 GHz, which cannot be reached with a GaAs-based photodetector sufficiently large for use with multi-mode fibers.

Multi-mode fibers have optical cores with diameters of 50 microns (μm) and 62.5 μm, which are significantly larger than the 8-10 μm core diameters of single-mode fibers. Accordingly, for a photodetector to be configured for use with a multi-mode fiber, the optical window of the photodetector must be large enough to enable efficient coupling to the large diameter optical core of a multi-mode fiber. Therefore, a diameter of the photodetector layer structure must be significantly larger than what is required for efficient coupling to a single-mode fiber. However, the capacitance of a photodetector, which is inversely related to the bandwidth at which the photodetector can operate, is a function of the diameter of the photodetector layer structure. In other words, a photodetector configured to operate with a multi-mode fiber has significantly more capacitance, and therefore lower bandwidth capabilities, than a photodetector configured to operate with a single-mode fiber. Conventional photodetectors configured for use with multi-mode fibers are limited to bandwidths of about 30 GHz. As new generations of optical communications systems require bandwidths of at least 50 GHz (e.g., data rates of 224 gigabits per second), technical problems exist regarding photodetectors that are capable of efficient optical coupling to multi-mode fibers and that are able to operate at sufficiently high bandwidth.

Conventional InP-based photodetectors, with InGaAs as the absorbing material, are predominantly used for single-mode fiber (SMF) optical links at wavelengths in the C-band (i.e., around 1550 nm) and O-band (i.e., around 1310 nm). At such wavelengths, InP-based photodetectors with InGaAs as the absorbing material have similar optical absorption characteristics as GaAs-based photodetectors at 850 nm and therefore suffer from the same bandwidth limitations as GaAs-based photodetectors. Additionally, for wavelengths in the range of 980-1100 nm (i.e., the longer wavelength range provided by GaAs-based VCSEL technology), the InGaAs used as the absorbing material suffers from increased dark current and high barriers for charge carrier transport, thus limiting the operating speed of the device.

Some embodiments of the present invention provide an InP-based photodetector (e.g., a PIN-type photodetector and/or a PIN photodiode) capable of operating at bandwidths of at least 50 GHz at wavelengths where GaAs-based VCSELs operate, while being large enough to be multi-mode fiber compatible. In some embodiments, the photodetector enables detection of an optical signal from a multi-mode fiber with sufficient efficiency, responsivity, and bandwidth for the baud rates expected for XDR (e.g., 112 Gbaud PAM4, 74 Gbaud PAM6) at wavelengths where GaAs-based VCSELs are expected to exhibit optimum performance in terms of modulation speed (e.g., 980 nm). Furthermore, some embodiments of the present invention provide bandwidths up to and greater than 50 GHz that can be achieved at sufficient quantum efficiency (e.g., greater than or equal to 65%) and responsivity (e.g., greater than 0.5 A/W) with a photodetector large enough for detecting XDR signals from a multi-mode fiber (e.g., an optical window greater than or equal to 20 μm).

In some embodiments, the present invention is directed to an InP-based photodetector with sufficient bandwidth for XDR (e.g., 224 Gbit/s) at the short wavelengths where GaAs-based VCSELs operate. The photodetector may have sufficiently low capacitance per unit area while being large enough to detect signals from an MMF with high efficiency (e.g., greater than or equal to 65%). The photodetector may take advantage of the high optical absorption coefficient of InGaAlAs at short wavelengths and the high electron drift velocity in InP at moderate electric fields. In some embodiments, the optical absorption and carrier drift processes in the photodetector may be substantially separated. The photodetector may include an absorption layer of InGaAlAs lattice-matched to InP with an alloy composition that minimizes, if not eliminates, the conduction band discontinuity, which minimizes the energetic barriers to transport for electrons and results in high-speed operation of the device. In addition, the alloy composition may have a bandgap slightly lower than the target energy of the detection wavelength range, which lowers the dark current, reduces the barriers for charge carriers, and enables higher bandwidth as compared to a conventional InGaAs absorbing layer lattice-matched to InP.

In some embodiments, the present invention is directed to a photodetector configured to detect light having a wavelength within the range of 900 to 1100 nm based on an InGaAlAs absorber region and/or layer. For example, the photodetector may include a composition of 22-24% of aluminum in InGaAlAs lattice-matched to InP, which substantially eliminates the conduction band discontinuity (i.e., ΔE_{c}=0 eV).

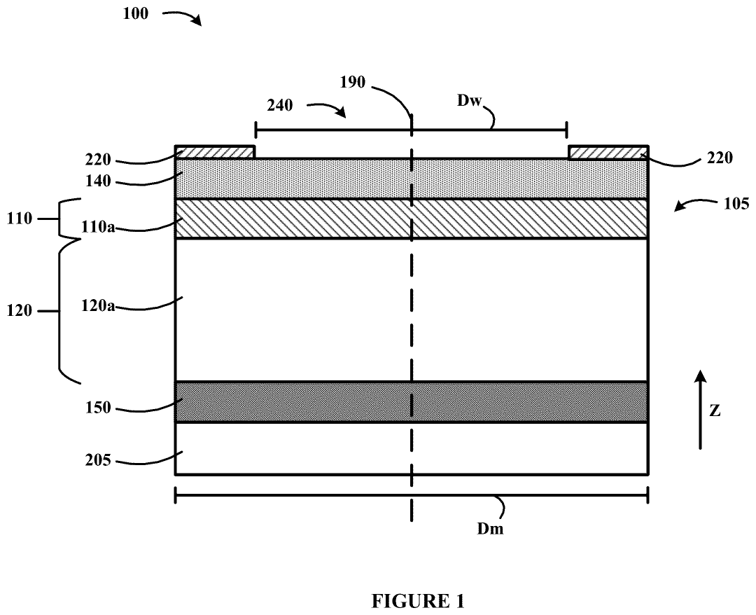

FIG. 1 illustrates a cross-section of an example layer structure 105 of a photodetector 100, in accordance with an embodiment of the invention. In particular, the cross-section of FIG. 1 is taken in a plane that is substantially parallel to a detection axis 190 of the photodetector 100. In some embodiments, the layer structure 105 and/or the photodetector 100 are configured to detect light in a particular wavelength range. For example, the particular wavelength range may be between about 940 nm and about 1150 nm, such as between about 960 nm and 1200 nm (e.g., between about 980 nm and 1100 nm). Additionally, or alternatively, the layer structure 105 and/or the photodetector 100 may be configured for use with multi-mode fibers at bandwidths equal to or greater than 50 GHz.

As shown in FIG. 1, the layer structure 105 may be formed on a substrate 205. For example, the substrate 205 may be an InP substrate and/or the like. As also shown in FIG. 1, the layer structure 105 of the photodetector 100 may include an absorber region 110, a collector region 120, a first peripheral layer 140, and a second peripheral layer 150. In some embodiments, and as shown in FIG. 1, the photodetector 100 may include a first contact layer 220, where a portion of the first contact layer 220 is removed to form an optical window 240 of the photodetector 100.

As shown in FIG. 1, the absorber region 110 and the collector region 120 are aligned with one another along the detection axis 190. In some embodiments, and as shown in FIG. 1, the absorber region 110 and the collector region 120 may not overlap (i.e., in a plane substantially perpendicular to the detection axis 190). Additionally, or alternatively, the absorber region 110 may have an absorber thickness in a direction substantially parallel to the detection axis 190, and the collector region 120 may have a collector thickness in a direction substantially parallel to the detection axis 190. In some embodiments, the collector thickness may be greater than the absorber thickness. For example, the absorber region 110 may have an absorber thickness of between about 0.1 μm and 0.6 μm (e.g., about 0.25 μm), and the collector region 120 may have a collector thickness of between about 1 μm and 3 μm (e.g., about 2 μm).

As shown in FIG. 1, the absorber region 110 may be formed from a single absorber layer 110a. For example, the absorber layer 110a may consist essentially of a quaternary material, such as InGaAlAs (e.g., with 23% aluminum and 24% gallium). As another example, the absorber layer 110a may include and/or consist essentially of In_{0.53}Ga_{0.24}Al_{0.23}As. As yet another example, the absorber layer 110a may include and/or consist essentially of a composition of In_{1-x-y}GaₓAl_{y}As with an A1 composition of about 22%. In some embodiments, the absorber layer 110a may be lattice-matched to the collector region 120 and/or a material forming the collector region 120. That is, a crystal structure of the absorber layer 110a may be lattice-matched to a crystal structure of the collector region 120 and/or a material forming the collector region 120. Additionally, or alternatively, the absorber layer 110a may be intrinsic and/or undoped (e.g., having a designed dopant density of less than 3×10¹⁴ atoms/cm³).

In some embodiments, the absorber region 110 and/or the absorber layer 110a may include and/or consist essentially of a material having an absorption coefficient of greater than 5,000 cm⁻¹ in the particular wavelength range of the photodetector. For example, the absorber region 110 and/or the absorber layer 110a may include and/or consist essentially of a material having an absorption coefficient of between about 20,000 cm⁻¹ and 60,000 cm⁻¹ in the particular wavelength range of the photodetector. Additionally, or alternatively, the absorber region 110 and/or the absorber layer 110a may include and/or consist essentially of a material having an absorption coefficient sufficiently high enough for an absorption length of an optical beam or optical signals in the particular wavelength range to be less than or equal to the absorber thickness.

Additionally, or alternatively, the absorber layer 110a may have a bandgap of about 1.05 eV, which corresponds to a wavelength of about 1090 nm. For example, the absorber layer 110a may be InGaAlAs having a high absorption coefficient of about 40,000 cm⁻¹ at 980 nm. Such an absorption coefficient allows for a thin absorber layer 110a (e.g., between about 0.35 and 0.4 μm) for sufficient quantum efficiency (e.g., about 65% or greater) and responsivity (e.g., 0.5 A/W). In operation, electrons and holes generated in the absorber layer 110a may, therefore, be rapidly transported to the collector region 120 and the first peripheral layer 140, respectively. In some embodiments, the absorber layer 110a may include and/or consist essentially of a quaternary material having an absorber conduction band energy that is approximately equal to a collector conduction band energy of collector material of the collector region 120.

As shown in FIG. 1, the collector region 120 may be formed from a single collector layer 120a. In some embodiments, the collector layer 120a may include a collector material that is substantially transparent to a particular wavelength range (e.g., between about 940 nm and about 1150 nm). For example, the collector layer 120a may consist essentially of a collector material, such as InP (e.g., intrinsic InP, undoped InP, InP having a designed dopant density of less than 3×10¹⁴ atoms/cm³, and/or the like). Electrons entering the collector region 120 may drift through the collector region 120 at high velocity (e.g., about 2.5×10⁷ cm/s) if an applied electric field is moderate (e.g., around 10-15 kV/cm). Therefore, the collector region 120 may be thick (e.g., about 2 μm), while having a short enough electron transit time for a high transit-time-limited bandwidth.

In some embodiments, the collector region 120 and/or the collector layer 120a may include and/or consist essentially of a material that is substantially transparent to the particular wavelength range because an absorption coefficient of the material at the particular wavelength is sufficiently small. For example, the collector region 120 and/or the collector layer 120a may include and/or consist essentially of a material having an absorption coefficient of 10,000 cm⁻¹, 1,000 cm⁻¹ or less in the particular wavelength range. Additionally, or alternatively, the collector region 120 and/or the collector layer 120a may include and/or consist essentially of a material having an absorption coefficient sufficiently low enough to allow an absorption length of an optical beam or optical signals in the particular wavelength range to be greater than the collector thickness. As noted, the collector region 120 and/or the collector layer 120a may include and/or consist essentially of a collector material having a collector conduction band energy that is approximately equal to an absorber conduction band energy of a quaternary material of the absorber region 110 and/or the absorber layer 110a.

In some embodiments, the absorber region 110 and the collector region 120 may form a depletion region that is thicker than a conventional depletion region for a conventional photodiode. Such a thicker depletion region provides a lower capacitance per unit area. Therefore, such a depletion region may achieve a high capacitance-limited bandwidth for a photodiode large enough to be compatible with multi-mode fibers.

As shown in FIG. 1, the layer structure 105 of the photodetector 100 may include the first peripheral layer 140 adjacent the absorber region 110 along the detection axis 190. In some embodiments, the first peripheral layer 140 may be lattice-matched to the collector material of the collector region 120 (e.g., InP). That is, a crystal structure of the first peripheral layer 140 may be lattice-matched to a crystal structure of the collector material of the collector region 120. For example, the first peripheral layer 140 may include and/or consist essentially of In_{0.52}AlAs. Additionally, or alternatively, the first peripheral layer 140 may include and/or consist essentially of p-type doped InP or p-type doped InAlAs. For example, the first peripheral layer 140 may include and/or consist essentially of InP doped with zinc, InAlAs doped with zinc, InP doped with carbon, or InAlAs doped with carbon.

As noted, in some embodiments, the first peripheral layer 140 may include and/or consist essentially of InAlAs doped with carbon. Such embodiments may provide performance advantages over others. For example, an InAlAs layer may provide a relatively low barrier for holes by having a low valence band discontinuity (AEᵥ) with respect to the absorber region 110 (e.g., InGaAlAs) of about 0.13 eV. Furthermore, an InAlAs layer may be doped with carbon as a p-type dopant instead of zinc. Carbon atoms do not diffuse as readily into the undoped (or low doped) absorber region 110 (e.g., InGaAlAs) and the collector region 120 (e.g., intrinsic InP) below the InAlAs as compared to zinc, which further improves device performance by reducing background doping in the absorber and collector regions/layers.

As shown in FIG. 1, the layer structure 105 of the photodetector 100 may include the second peripheral layer 150 adjacent the collector region 120 along the detection axis 190. In some embodiments, the second peripheral layer 150 may include and/or consist essentially of n-type doped InP. For example, highly doped InP (e.g., a dopant density of greater than 5×10¹⁷ atoms/cm³) may form the second peripheral layer 150.

In some embodiments, the layer structure 105 of the photodetector 100 may include only the first peripheral layer 140, the absorber layer 110a, the collector layer 120a, and the second peripheral layer 150 and may not include any intermediate layers between the absorber layer 110a and the collector layer 120a (e.g., to ease carrier transport across the interfaces). Furthermore, each of the first peripheral layer 140, the absorber layer 110a, the collector layer 120a, and the second peripheral layer 150 may consist essentially of a single material. In such embodiments, the layer structure 105 may be formed using a simpler epitaxy process than conventional layer structures that include one or more intermediate layers, more than one layer per region, and/or more than one material per layer.

In some embodiments, the layer structure 105 and/or the photodetector 100 may be configured such that, when an appropriate bias voltage is applied to the photodetector 100 (e.g., via contact pads in electrical communication with and corresponding to each of the first peripheral layer 140 and the second peripheral layer 150), appropriate electric fields are generated within the absorber region 110 and the collector region 120. For example, the layer structure 105 and/or the photodetector 100 may be configured such that, when a bias voltage of between about 1 volt and 5 volts is applied to the photodetector 100, an electric field is generated within the absorber region 110 and the collector region 120 that causes the absorber region 110 and the collector region 120 to be substantially depleted of free charge carriers. In some embodiments, the electric field generated within the collector region 120 may cause electrons within the collector region 120 to be transported away from the absorber region 110 toward the second peripheral layer 150 (e.g., in the negative z-direction). Additionally, or alternatively, the electric field generated within the absorber region 110 may cause holes within the absorber region 110 to be transported away from the collector region 120 toward the first peripheral layer 140 (e.g., in the positive z-direction). In some embodiments, the layer structure and the photodetector 100 may be configured such that an amplitude of the electric field generated within the absorber region 110 may cause the holes within the absorber region 110 to reach their saturation velocity.

In operation, light (e.g., an optical beam, optical signal, and/or the like characterized by the particular wavelength range and/or one or more wavelengths within the particular wavelength range) may enter the layer structure 105 of the photodetector 100 through the first peripheral layer 140 traveling in the negative z-direction. The light may interact with material within the absorber region 110 to generate free holes and free electrons. The free holes may be accelerated toward the first peripheral layer 140 by the electric field within the absorber region 110. The free electrons may be accelerated across the absorber region 110 and the collector region 120 toward the second peripheral layer 150 by the electric fields within the absorber region 110 and the collector region 120. For example, the free holes may be substantially accelerated in the positive z-direction, and the free electrons may be substantially accelerated in the negative z-direction.

In some embodiments, and as shown in FIG. 1, the z-direction may be substantially parallel to the detection axis 190. For example, the primary direction of acceleration of the free holes and/or the free electrons may define the z-direction and/or the detection axis 190.

As noted, and as shown in FIG. 1, the photodetector 100 may include the first contact layer 220. In some embodiments, the first contact layer 220 may be electrically coupled to the first peripheral layer 140. In some embodiments, the first contact layer 220 is configured to provide a low resistance electrical connection to the first peripheral layer 140. For example, the first contact layer 220 may include InGaAs. In some embodiments, the first contact layer 220 may include heavily p-type doped InGaAs. As noted, the first contact layer 220 may be removed from the optical window 240 of the photodetector 100. For example, any portion of the first contact layer 220 present in the optical window 240 after the forming of the first contact layer 220 may be removed (e.g., via etching) such that the optical window 240 does not contain the first contact layer 220 and undesired absorption of light incident on the optical window by the first contact layer 220 is prevented. As show in FIG. 1, the optical window 240 is positioned in front of the absorber region 110 along the detection axis 190 of the photodetector for light incident on the photodetector 100 in a negative z-direction.

In some embodiments, one or more metallized and/or conductive elements (not shown) may electrically couple the first peripheral layer 140 and the first contact layer 220 to a first contact pad (also not shown). Similarly, one or more metallized and/or conductive elements (not shown) may electrically couple the second peripheral layer 150 to a second contact pad (also not shown).

In some embodiments, the layer structure 105 may define a mesa diameter Dₘ in a direction that is transverse (e.g., perpendicular) to the detection axis 190. For example, at least an upper portion of the layer structure 105 (e.g., including the collector region 120, the absorber region 110, and/or the first peripheral layer 140) may have a cylindrical shape, and the first contact layer 220 may have an annular shape (e.g., when viewed in a plane substantially perpendicular to the detection axis 190) defining a substantially circular optical window 240 having a window diameter D_{w}. In some embodiments, an anti-reflective coating may be disposed on the first peripheral layer 140 within the optical window 240.

In some embodiments, and as noted, the photodetector 100 and/or the layer structure 105 may be configured for use with a multi-mode fiber. In this regard, the mesa diameter Dₘ and/or the window diameter D_{w} may be configured for use and/or coupling to a multi-mode fiber. For example, the window diameter D_{w} may be 15 μm, 20 μm, 25 μm, or wider (e.g., 62.5 μm). As another example, the mesa diameter Dₘ may be 15 μm, 20 μm, 25 μm, 30 μm, or wider (e.g., 125 μm). In some embodiments, even with a large window diameter D_{w} (e.g., between about 15 μm and 62.5 μm) and/or a large mesa diameter Dₘ (e.g., between about 20 μm and 125 μm, the photodetector 100 may be configured to operate at bandwidths greater than 50 GHz. For example, the photodetector 100 may be configured for use with and/or coupling to a multi-mode optical fiber and for operation at data rates of 100 Gbit/s or more. In some embodiments, the photodetector 100 may be configured for use with and/or coupling to single-mode fibers and may have accordingly smaller window diameters and/or mesa diameters and be configured to operate at bandwidths greater than 50 GHz.

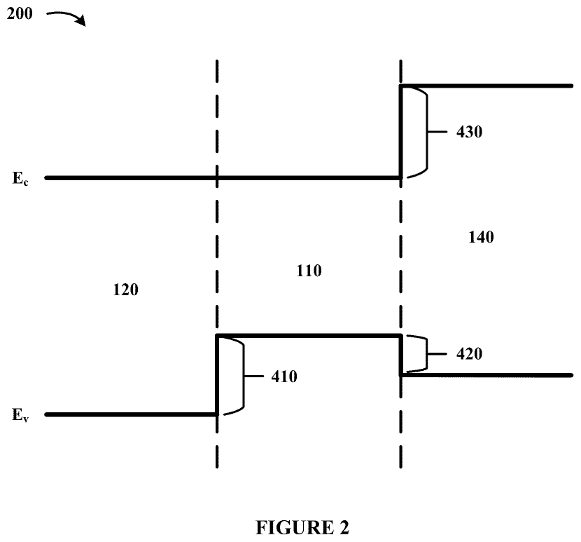

As noted, FIG. 2 illustrates a band diagram 200 for the transition between layers within the photodetector 100 of FIG. 1, in accordance with an embodiment of the invention. In particular, the band diagram 200 of FIG. 2 is a band diagram at zero-voltage bias corresponding to the layer structure 105 in which the collector region 120 is intrinsic InP, the absorber region 110 is In_{0.53}Ga_{0.24}Al_{0.23}As, and the first peripheral layer 140 is In_{0.52}AlAs. In such a layer structure 105, the collector region 120 has a band gap E_{g} (e.g., a difference between the conduction band energy (E_{c}) and the valance band energy (Eᵥ)) of about 1.35 eV, the absorber region 110 has a band gap E_{g} of about 1.05 eV, and the first peripheral layer 140 has a band gap E_{g} of about 1.49 eV.

As shown in FIG. 2, for such a layer structure 105, a valence band discontinuity 410 exists between the collector region 120 and the absorber region 110, and another valence band discontinuity 420 exists between the absorber region 110 and the first peripheral layer 140. However, the valence band discontinuities 410 and 420 are relatively small as compared to conventional photodiode layer structures. For example, the valence band discontinuity 410 may be about 300 meV, and the other valence band discontinuity 420 may be about 130 meV. Such low valence band discontinuities permit holes to be rapidly transmitted from the absorber region 110 to the first peripheral layer 140, which improves efficiency and performance of the photodetector 100.

As also shown in FIG. 2, for such a layer structure 105, a conduction band discontinuity 430 exists between the first peripheral layer 140 and the absorber region 110 and no conduction band discontinuity exists between the absorber region 110 and the collector region 120 (i.e., the absorber conduction band energy and the collector conduction band energy are approximately equal). In some embodiments, the conduction band discontinuity 430 may be about 320 meV. Such low or non-existent conduction band discontinuities permit electrons to be rapidly transmitted from the absorber region 110 to the collector region 120, which improves efficiency and performance of the photodetector 100.

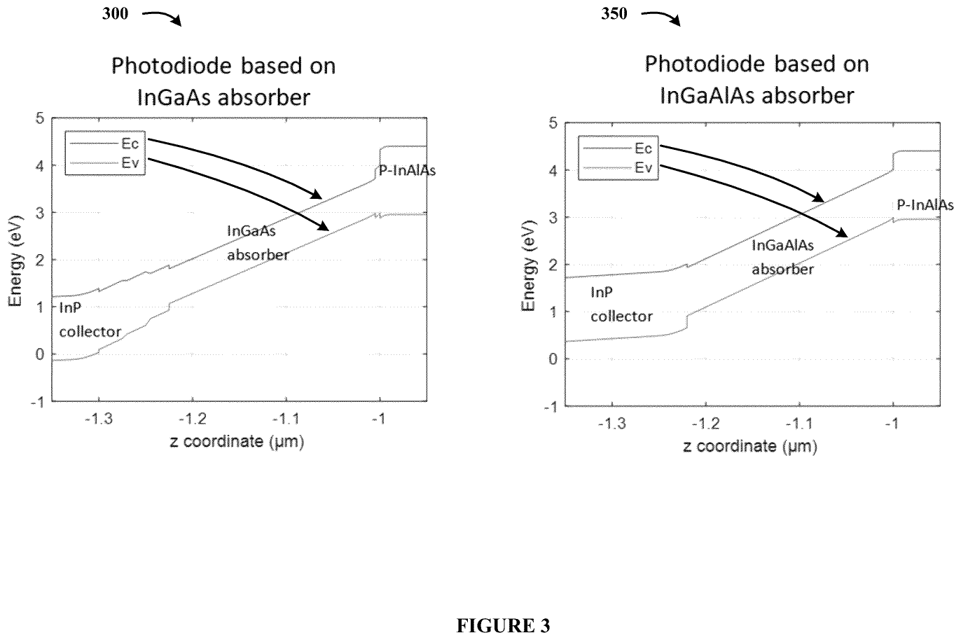

FIG. 3 illustrates respective band diagrams 300 and 350 for a conventional active region and an exemplary active region at a reverse bias voltage of 3 V, in accordance with an embodiment of the invention. In particular, the band diagram 300 is for a conventional photodiode with an InP collector region, an InGaAs absorber region, and a p-type doped InAlAs peripheral layer. The band diagram 350 is for an exemplary photodiode with an InP collector region, an InGaAlAs absorber region, and a p-type doped InAlAs peripheral layer (e.g., similar to one or more of the exemplary photodiodes shown and described herein with respect to FIG. 1). Each photodiode of FIG. 3 includes a 1.6 μm-thick collector region and a 0.22 μm-thick absorber region. With a background doping density of less than about 3×10¹⁴ atoms/cm³, the electric fields in the collector region (e.g., about 10 kV/cm) and the absorber region (e.g., about 35 kV/cm) are more uniform and on target in the exemplary active region as compared to the conventional active region.

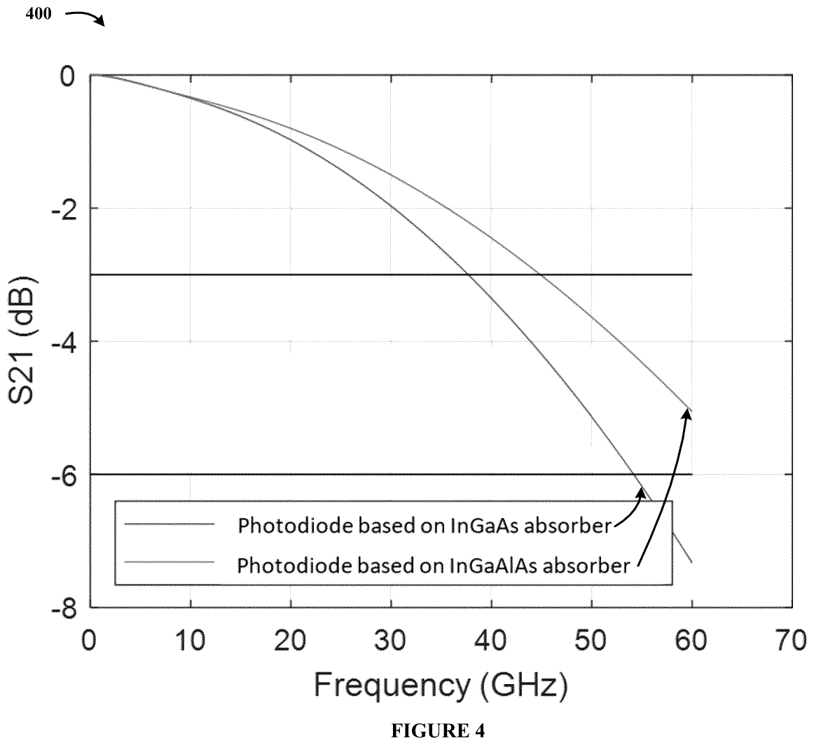

FIG. 4 illustrates a graph 400 plotting respective frequency responses for a conventional active region and an exemplary active region, in accordance with an embodiment of the invention. In particular, the graph 400 plots the −3 dB bandwidth results of a simulated structure with a conventional InGaAs absorber region and another simulated structure with an exemplary InGaAlAs absorber region. As shown in FIG. 4, the exemplary InGaAlAs absorber region results in a higher bandwidth (e.g., about 7 GHz higher) than the conventional InGaAs absorber region. Accordingly, photodiodes including an exemplary InGaAlAs absorber region may support higher bandwidth signal transmission than conventional photodiodes.

Some embodiments of photodiodes in accordance with the present invention include separate absorber regions and collector regions that are configured to provide sufficiently high bandwidth when the mesa diameter and optical window of the photodetector are sufficiently large enough for efficient optical coupling to a multi-mode fiber. Photodetectors, such as PIN-type photodiodes, may be characterized by a detector capacitance. The greater the detector capacitance, the longer it typically takes for the photodetector to adjust to and/or detect changes in an incoming optical signal, which reduces the bandwidth at which the photodetector may operate. The detector capacitance is typically an inverse function of the thickness of the depletion region of the photodetector in the direction substantially parallel to the detection axis (e.g., the distance between the first peripheral layer 140 and the second peripheral layer 150 and/or the combined thickness of the absorber region and the collector region). Thus, a thicker photodetector depletion region typically results in lower detector capacitance (e.g., with all other variables held constant).

Some embodiments of photodetectors in accordance with the present invention overcome these technical problems by including a separate absorber region and collector region, where the absorber region includes a quaternary material (e.g., InGaAlAs) that has a conduction band difference with a collector material of the collector region that is approximately zero. Furthermore, the absorber region may enable efficient absorption of light characterized by a particular wavelength range such that the absorber layer may be thin (e.g., 0.1 μm to 0.6 μm). The thinness of the absorber region may allow for short drift times for free holes and free electrons generated by interaction of light with the absorbing material of the absorber region. Additionally, the material of the collector region may be configured to cause high acceleration and fast transport of free electrons such that the collector region may be relatively thick (e.g., 1 μm to 3 μm) to provide a low detector capacitance, while still enabling a short free electron drift time. Furthermore, because the quaternary material and the collector material have a conduction band difference of approximately zero, the photodetector may omit an intermediate layer to enable efficient transport of free holes and free electrons across the boundary between the absorber region and the collector region, which simplifies manufacturing of the photodetector. Finally, due to the low capacitance per area (e.g., area taken in a plane perpendicular to the detection axis of the photodetector), some embodiments of photodetectors may be fabricated with optical windows and/or mesa diameters that are large enough to enable efficient coupling to multi-mode fibers, while still enabling the photodetectors to operate a high bandwidth (e.g., greater than 50 GHz).

As will be appreciated by one of ordinary skill in the art in view of this disclosure, the present invention may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention and that this invention is not to be limited to the specific constructions and arrangements shown and described, as various other changes, combinations, omissions, modifications and substitutions, in addition to those set forth in the above paragraphs, are possible. Those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A photodetector configured to detect light in a particular wavelength range, the photodetector comprising:
an absorber region comprising a quaternary material, wherein the absorber region has an absorber thickness in a direction that is substantially parallel to a detection axis of the photodetector, and wherein the quaternary material has an absorber conduction band energy; and
a collector region comprising a collector material that is substantially transparent to the particular wavelength range, wherein the collector region has a collector thickness in the direction that is substantially parallel to the detection axis, and wherein the collector material has a collector conduction band energy;
wherein the absorber conduction band energy and the collector conduction band energy are approximately equal.

2. The photodetector of claim 1, comprising an optical window configured for use with a multi-mode optical fiber, wherein the optical window is positioned in front of the absorber region along the detection axis of the photodetector.

3. The photodetector of claim 1, wherein the absorber region consists essentially of the quaternary material.

4. The photodetector of claim 1, wherein the quaternary material is InGaAlAs.

5. The photodetector of claim 1, wherein the collector material is InP.

6. The photodetector of claim 5, wherein the InP is intrinsic InP.

7. The photodetector of claim 1, wherein the collector region consists essentially of the collector material.

8. The photodetector of claim 1, wherein the quaternary material is lattice-matched to the collector material.

9. The photodetector of claim 1, wherein the quaternary material and the collector material are adjacent to each other along the detection axis.

10. The photodetector of claim 1, comprising a peripheral layer adjacent the absorber region along the detection axis.

11. The photodetector of claim 10, wherein the peripheral layer is p-type doped InAlAs.

12. The photodetector of claim 11, wherein the p-type doped InAlAs is doped with carbon.

13. The photodetector of claim 10, wherein the peripheral layer is lattice-matched to the collector material.

14. The photodetector of claim 1, wherein the particular wavelength range is between 940 nanometers and 1150 nanometers.

15. A photodetector configured to detect light in a particular wavelength range, the photodetector comprising:
a quaternary material having an absorber thickness in a direction that is substantially parallel to a detection axis of the photodetector;
a collector material adjacent to a first side of the quaternary material along the detection axis, wherein the collector material is substantially transparent to the particular wavelength range, and wherein the collector material has a collector thickness in the direction that is substantially parallel to the detection axis; and
a peripheral layer adjacent to a second side of the quaternary material along the detection axis.

16. The photodetector of claim 15, wherein the quaternary material is InGaAlAs.

17. The photodetector of claim 15, wherein the collector material is intrinsic InP.

18. The photodetector of claim 15, wherein the peripheral layer is p-type doped InAlAs doped with carbon.

19. A photodetector configured to detect light in a particular wavelength range, the photodetector comprising:
a collector material that is substantially transparent to the particular wavelength range, wherein the collector material has a collector thickness in a direction that is substantially parallel to a detection axis of the photodetector;
a quaternary material having an absorber thickness in the direction that is substantially parallel to the detection axis, wherein the quaternary material is lattice-matched to the collector material, and wherein a conduction band difference between the collector material and the quaternary material is approximately zero; and
a peripheral layer adjacent to the quaternary material along the detection axis, wherein the peripheral layer is doped with carbon.

20. The photodetector of claim 19, wherein the quaternary material is InGaAlAs, the collector material is intrinsic InP, and the peripheral layer is InAlAs doped with carbon.
